(19) United States
(12) Patent Application Publication
(10) Pub. No.: US 2025/0046551 A1
(43) Pub. Date: Feb. 6, 2025

(54) PHASE-CHANGE MATERIAL SWITCH

(71) Applicants: Commissariat à I'Énergie Atomique et aux Énergies Alternatives, Paris (FR); Institut Polytechnique de Grenoble, Grenoble (FR); Université Grenoble Alpes, Saint Martin D'Heres (FR)

(72) Inventors: Bruno Reig, Grenoble (FR); Clémence Hellion, Grenoble (FR); Ismaël Charlet, Grenoble (FR); Marjolaine Allain, Grenoble (FR); Ayoub Naoui, Grenoble (FR)

(73) Assignees: Commissariat à I'Énergie Atomique et aux Énergies Alternatives, Paris (FR); Institut Polytechnique de Grenoble, Grenoble (FR); Université Grenoble Alpes, Saint Martin D'Heres (FR)

(21) Appl. No.: 18/787,124

(22) Filed: Jul. 29, 2024

(30) Foreign Application Priority Data
Aug. 3, 2023 (FR) 2308452

(51) Int. Cl. H01H 37/32; G02B 6/42; H01H 11/00; H10N 70/00; H10N 70/20

(52) U.S. Cl. CPC H01H 37/32; H01H 11/00; H10N 70/026; H10N 70/063; H10N 70/231; H10N 70/257; H10N 70/823; G02B 6/4204

(57) ABSTRACT

The present disclosure relates to phase-change-based material switch formed on a support substrate, and including: a region made of said phase-change material coupling first and second conduction electrodes of the switch; and a waveguide interposed between the support substrate and the region made of said phase-change material, and including a center region made of a first material having a first optical index surrounded by a peripheral region made of a second material having a second optical index less than the first optical index.

### CROSS REFERENCE TO RELATED APPLICATIONS

This application claims priority to French application number 2308452, filed Aug. 3, 2023, the contents of which is incorporated by reference in its entirety.

### TECHNICAL FIELD

The present description relates generally to electronic devices, particularly switches. The present description relates more particularly to the switches based on phase-change material.

### BACKGROUND ART

Various applications use switches to block or allow, according to the state of a signal for controlling the switch, the flowing of an electric signal between different parts of an electronic circuit. In the telecommunications field, switches for radiofrequency signals, also called radiofrequency (RF) switches, are integrated in various types of devices such as reconfigurable filters, phase shifters, transmitarray or reflectarray reconfigurable antennas, etc. These switches particularly allow various functions to be implemented: RF signal routing, switching of an antenna between emitting and receiving modes, activation of a filter corresponding to a given frequency band, etc. The RF switches are of particular use in designing and implementing reconfigurable radiating surfaces in the sub-terahertz frequency bands, for example in the order of one or several hundreds of gigahertz, for applications in medical imaging and industrial monitoring, earth and deep space observation, also in systems and radars for broadband telecommunications.

RF switches are usually implemented, according to the desired performance level, based on field-effect transistors, PIN diodes, electromechanical relays or MEMS (MicroElectroMechanical System) components. However, these switches are not fully satisfactory, especially for high-frequency applications, for example around 100 GHz. Performances of a RF switch depend on a parameter called Figure of Merit (FoM), equal to the product of the ON state resistance R_{ON} by the OFF state capacitance C_{OFF} of the RF switch. The resistance R_{ON} and capacitance C_{OFF} reflect insertion losses of the switch in the ON state, and an isolation of the switch in the OFF state, respectively, two quantities to be minimized for RF applications.

In order to exceed the limitations of the above-mentioned RF switches, phase-change-material-based switches able to switch between an electrically conductive crystal phase and an electrically insulating amorphous phase were proposed. Phase-change-material-based switches have, compared to usual RF switches based on transistors and PIN diodes, a figure of merit around ten times lower. For example, the figure of merit is about 100 fs for RF switches based on transistors and PIN diodes, as compared to about 10 fs for the RF phase-change-material-based switches. The latter further have the advantage to have non-volatile ON and OFF states, the switch requiring no energy consumption to be kept in either state. The RF MEMS-based switches could achieve relatively low figures of merit, but have various drawbacks, particularly accuracy and high fingerprint, and have volatile states.

Among phase-change-material-based switches, direct heating switches, controlled by flowing a current through the phase-change material, or indirect heating switches, for example by flowing a current pulse through an heating element electrically insulated from the phase-change material, were proposed. However, these switches have various drawbacks. In the direct heating switches, the control signal disturbs the RF signal transmitted between the conduction electrodes of the switch. In the indirect heating switches, the heating element generates a parasitic capacitance and parasitic resistances. Furthermore, the indirect heating switches include metal conductive tracks used to transmit the control signal from a current source up to the heating element. In the case where the RF switch is a part of a reconfigurable antenna, providing these tracks highly disturbs the field radiated by the antenna.

In order to overcome these drawbacks, RF phase-change-material-based and optically-actuated switches were proposed. Optical actuation is in these switches implemented by direct laser irradiation of the phase-change material. However, this requires a precise aligning of the laser beam with the phase-change material, thus highly complicating the integration of such switches particularly in reconfigurable antenna applications that could include hundreds of switches.

### SUMMARY OF INVENTION

There is a need to overcome some or part of the drawbacks in existing switches. Particularly, it would be desirable to optimize the implementation of the optically-actuated phase-change material switches.

To this end, one embodiment provides an optically actuated phase-change-material-based switch formed on a support substrate, and comprising:
a region made of phase-change material coupling first and second conduction electrodes of the switch; and
a waveguide interposed between the support substrate and the region made of said phase-change material, and including a center region made of a first material having a first optical index surrounded by a peripheral region made of a second material having a second optical index lower than the first optical index.

According to one embodiment, the center region of the waveguide is separated from the region made of said phase-change material with a distance less than, or equal to, 100 nm, preferably less than, or equal to, 50 nm, more preferably equal to around 20 nm.

According to one embodiment, the waveguide further comprises an input coupling element having a Bragg structure comprising evenly spaced portions of concentric rings.

According to one embodiment, the switch further comprises a laser source intended to irradiate the coupling element with a laser radiation having a center wavelength equal to around 915 nm.

According to one embodiment, the input coupling element is separated from the support substrate with a distance equal to around 1,500 nm within more or less 100 nm.

According to one embodiment, the center region of the waveguide is separated from the support substrate with a distance equal to around 1,500 nm within more or less 100 nm.

According to one embodiment, the switch further comprises first and second conductive vias extending between the region made of said phase-change material and the first and second conduction electrodes, respectively.

According to one embodiment, the center region of the waveguide is separated from the first and second conductive vias with a distance higher than, or equal to, 0.3 μm.

According to one embodiment, the region made of said phase-change material is coated with a passivating layer.

According to one embodiment, the center and peripheral regions of the waveguide are made of silicon nitride and silicon oxide respectively.

According to one embodiment, the center region of the waveguide is around 300 nm high and around 600 nm wide.

Another embodiment provides a method for manufacturing an optically actuated phase-change-material-based switch comprising the consecutive following steps:
a) forming, on a support substrate, first and second conduction electrodes of the switch;
b) forming, on the support substrate, a waveguide including a center region made of a first material having a first optical index surrounded by a peripheral region made of a second material having a second optical index less than a first optical index; and
c) forming, on the support substrate, a region made of said phase-change material coupling the first and second conduction electrodes of the switch, the waveguide being interposed between the support substrate and the region made of said phase-change material.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1A is a schematic partial top view of an example phase-change-material-based switch according to one embodiment;

FIG. 1B and FIG. 1C are schematic partial sectional views along planes BB and CC shown in FIG. 1A, respectively, of the phase-change-material-based switch shown in FIG. 1A; and

FIG. 2A, FIG. 2B, FIG. 2C, FIG. 2D, and FIG. 2E are schematic partial sectional views along the plane CC shown in FIG. 1A illustrating consecutive steps of an example method for manufacturing the phase-change-material-based switch shown in FIGS. 1A, 1B, and 1C according to one embodiment.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, applications wherein may be provided phase-change-material-based switches are not described in detail, the embodiments and alternatives described being compatible with the conventional applications implementing switches.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

In the following disclosure, unless indicated otherwise, the “insulating” and “conductive” qualifiers mean electrically insulating and electrically conductive, respectively.

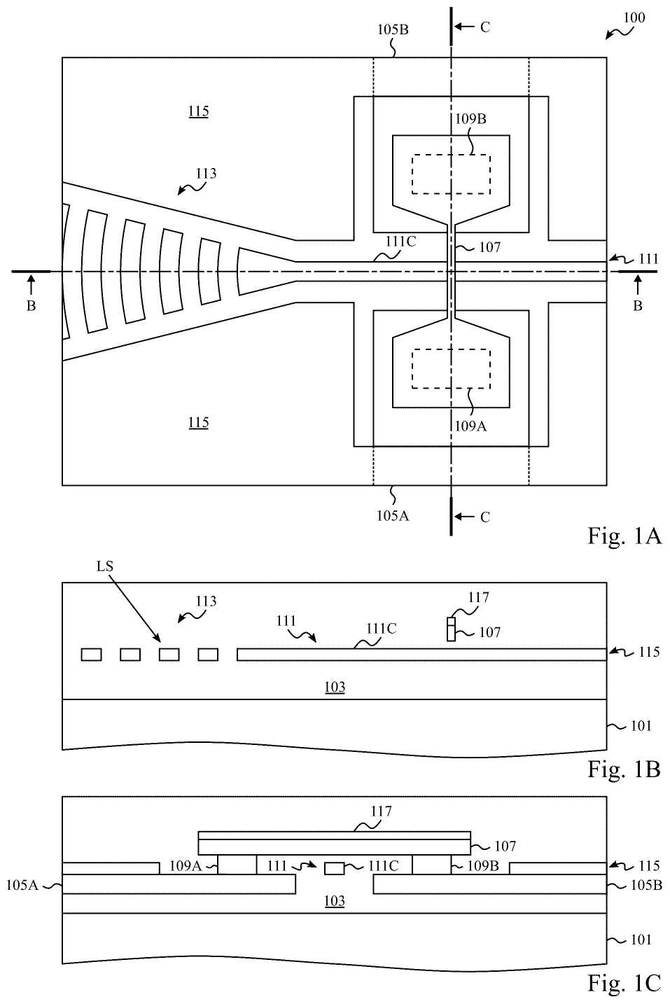

FIG. 1A is a schematic partial top view of an example phase-change-material-based switch 100 according to one embodiment. FIG. 1B and FIG. 1C are schematic partial sectional views along planes BB and CC shown in FIG. 1A, respectively, of the phase-change-material-based switch 100 shown in FIG. 1A. In the example shown, the plane BB is orthogonal to the conduction direction of the switch 100, and the plane CC is parallel to the conduction direction of the switch 100.

In the example shown, the switch 100 is formed on a support substrate 101. The support substrate 101 is for example a wafer or a piece of wafer made of a semiconductor material, e.g. silicon. Alternatively, the support substrate 101 could be made of an insulating material, for example made of glass, quartz, etc. In the orientation shown in FIGS. 1A, 1B, and 1C, planes BB and CC are orthogonal to the top face of the support substrate 101.

In the example shown, the support substrate 101 is coated with an insulating layer 103. In the orientation shown in FIGS. 1A, 1B, and 1C, the insulating layer 103 is located on, and in contact with, the top face of the support substrate 101. As an example, the layer 103 is an oxide layer, for example silicon oxide (SiO₂). The insulating layer 103 was not shown in FIG. 1A in order not to overload the drawing.

In the example shown, the switch 100 further comprises conduction electrodes 105A and 105B separated from the support substrate 101 with parts of the insulating layer 103. Parts of the insulating layer 103 are thus vertically interposed between the top face of the support substrate 101 and the conduction electrodes 105A and 105B. In the example shown, the conduction electrodes 105A and 105B are separated from each other by a part of the insulating layer 103 laterally extending therebetween. The conduction electrodes 105A and 105B are for example intended to be connected to a RF communication circuit, not shown in detail in the drawings. The conduction electrodes 105A and 105B are made of a conductive material. As an example, the conduction electrodes 105A and 105B are made of a metal, e.g. copper or alumina, or of a metal alloy. Furthermore, the conduction electrodes 105A and 105B may have a single layer or multilayer structure. In the case of the multilayer structure, the conduction electrodes 105A and 105B are for example formed of a stack comprising, from bottom to top in the orientation shown in FIGS. 1B and 1C:
a layer made of titanium having a thickness equal to around 10 nm, for example;
a layer made of a copper and alumina alloy having a thickness equal to around 440 nm, for example;
a layer made of titanium having a thickness equal to around 10 nm, for example;
a layer made of titanium nitride having a thickness equal to around 100 nm, for example.

In the example shown, the switch 100 further comprises a region 107 made of a phase-change material coupling the conduction electrodes 105A and 105B. In this example, the region 107 made of phase-change material vertically extends in line with a part of each conduction electrode 105A, 105B. A first end of the region 107 made of phase-change material is located in line with the conduction electrode 105A, and a second end, opposite the first end, of the region 107 is located in line with the conduction electrode 105B. As an example, the region 107 made of phase-change material has a thickness of around 100 nm.

In the example shown, conductive vias 109A and 109B vertically extend through a part of the insulating layer 103, from the bottom face of the region 107 made of phase-change material up to the top faces of the conduction electrodes 105A and 105B, respectively. The conductive vias 109A and 109B are located in the vicinity of first and second ends of the region 107 made of phase-change material, respectively, and allow the region 107 to be electrically connected to the conduction electrodes 105A and 105B, respectively. As an example, the conductive vias 109A and 109B are made of a metal, for example copper, alumina, or tungsten, or of a metal alloy.

In the example shown, the side faces of the conductive vias 109A and 109B are bordered or coated by the insulating layer 103. Furthermore, the side faces and the parts of the bottom face of the region 107 made of phase-change material not located in contact with the top faces of the conductive vias 109A and 109B are bordered or coated by the insulating layer 103.

For example, the region 107 made of phase-change material is made of a chalcogenide, i.e. a material or an alloy comprising at least one chalcogen element, for example a material of the group consisting of the germanium telluride (GeTe), antimony telluride (SbTe), or germanium-antimony telluride (GeSbTe, conventionally designated as “GST”). As an alternative, the region 107 is made of vanadium dioxide (VO₂).

Generally, the phase-change materials are able to toggle under a temperature change, between a crystal phase and an amorphous phase, the amorphous phase having an electric resistance higher than that of the crystal phase. In the case of the switch 100, one takes advantage of this phenomenon to obtain an OFF state avoiding a current to flow between the conduction electrodes 105A and 105B, when the material of the region 107 is in the amorphous phase, and a ON state allowing a current to flow between the conduction electrodes 105A and 105B, when the material of the region 107 is in the crystal phase.

In the example shown, the switch 100 further comprises a waveguide 111 interposed between the support substrate 101 and the region 107 made of phase-change material. In this example, the waveguide 111 laterally extends along a main direction significantly orthogonal to the conduction direction of the switch 100. In the example shown, the waveguide 111 comprises a center region 111C, or core, surrounded by an insulating peripheral region made of a part of the insulating layer 103. The center region 111C and the peripheral region of the waveguide 111 are made of materials selected so that a contrast in optical indexes is obtained, allowing an optical mode of interest emitted from a laser source LS to be confined and guided within the center region 111A. As an example, the laser source LS comprises a laser diode or a pulsed diode.

The center region 111C of the waveguide 111 has an optical index higher than that of the peripheral region. As an example, the center region 111C of the waveguide 111 is made of silicon nitride (SiN), and the peripheral region is made of silicon oxide. Using silicon nitride for implementing the center region 111C is advantageously compatible with the CMOS (Complementary Metal Oxide Semiconductor) manufacturing methods. Furthermore, the silicon nitride allows a great uniformity in thickness, a correct optical-wave confinement during the propagation in the waveguide 111, and low propagation losses to be obtained. For example, apart from the part located in line with the region 107 made of phase-change material, the center region 111C of the waveguide 111 is for example surrounded by a thickness of the material of the insulating layer 103 higher than 1.5 μm in order to restrict the propagation losses in the waveguide 111.

The plane CC shown in FIG. 1C is significantly orthogonal to a propagation direction of the laser radiation in the waveguide 111. In the example shown, the peripheral region of the waveguide 111 (insulating layer 103 in the present example) coats or borders the faces of the center region 111C parallel to the propagation direction of the laser radiation (side, bottom, and top faces of the center region 111C parallel to an axis orthogonal to a plane CC). In the present example, a part of the insulating layer 103 vertically extends from a face of the center region 111C located in line with the region 107 made of phase-change material (the top face of the center region 111C, in the orientation shown in FIG. 1C) up to a face of the region 107 made of phase-change material located opposite (the bottom face of the region 107, in the orientation shown in FIG. 1C).

In the example shown, the center region 111C is, in sectional view along the plane CC orthogonal to the propagation direction of the laser radiation in the waveguide 111, significantly rectangularly shaped in section. As an example, the section of the center region 111C has a width equal to around 600 nm and a height, or thickness, equal to around 300 nm. Furthermore, the center region 111C is separated from the region 107 made of phase-change material with a distance less than, or equal to, 100 nm, for example, less than, or equal to, 50 nm, for example equal to around 20 nm. In the present example, the distance separating the center region 111C from the region 107 made of phase-change material corresponds to a thickness of a part of the insulating layer 103 interposed between the center region 111C and the region 107 made of phase-change material. As an alternative, the region 107 made of phase-change material could be located on, and in contact with, the center region 111C of the waveguide 111.

Coupling the optical power of the radiation emitted within the center region 111C of the waveguide 111 with the phase-change material of the region 107 is performed via evanescent field. The inventors observed that the closer the center region 111C to the region 107, the higher optical coupling and the higher the reflection due to index change. In contrast, the further the center region 111C from the region 107, the lower the reflection and the lower the coupling ratio. For example, the distance separating the region 107 made of phase-change material from the center region 111C of the waveguide 111 is selected so that a compromise between absorbing the optical wave by the phase-change material of the region 107, and reflecting the optical wave on the input face of the region 107 made of phase-change material (the bottom face of the region 107, in the orientation shown in FIGS. 1B and 1C).

As an example, the center region 111C of the waveguide 111 is laterally separated from conductive vias 109A and 109B by a distance higher than, or equal to, 0.3 μm, in the case where the conductive vias 109A and 109B have, along the propagation axis of the radiation within the center region 111C of the waveguide 111, a side size less than 10 μm, and a distance higher than, or equal to, 0.5 μm, for example higher than, or equal to, 1 μm, in the case where the conductive vias 109A and 109B have, along the propagation axis of the radiation within the center region 111C of the waveguide 111, a side size higher than, or equal to, 10 μm. It allows absorbing, by the material of the conductive vias 109A and 109B, the radiation transmitted from the waveguide 111 to be avoided or restricted.

For example, the waveguide 111 is of the single-mode type, i.e. it is suitable for confining and guiding a single optical mode for each polarization type. For example, the waveguide 111 is more particularly suitable for confining and guiding a single optical mode selected among a null-order electric transverse mode (TEO), and a null-order magnetic transverse mode (TMO). Since the TEO and TMO modes are orthogonal to each other, they cannot couple to each other within the waveguide 111. The selection of the mode confined and guided by the waveguide 111, between the TEO mode and the TMO mode, is determined by the polarization of the laser source LS. In the case where the laser source LS emits a radiation having an electrical transverse polarization TE, the waveguide 111 is thus suitable for confining and guiding only the null-order electric transverse mode TEO.

As an example, the radiation emitted by the laser source LS has a center wavelength around 915 nm. It allows obtaining a compromise between absorbing the radiation by the phase-change material of the region 107, being even more important since the wavelength of the emitting of the laser source LS is low, and attenuating the radiation transmitted from the waveguide 111, being even more low since the wavelength of the emitting of the laser source LS is high. As an example, absorbing the radiation by the phase-change material of the region 107 is twice greater as the radiation wavelength is equal to around 915 nm than as it is equal to around 1,550 nm. Furthermore, in the case where the region 111C is made of silicon nitride, attenuating the radiation transmitted by the waveguide 111 goes too high at wavelengths less than 500 nm to allow a phase change of the material of the region 107 to be obtained.

For example, on the side of its end intended to be irradiated by the laser source LS, the waveguide 111 comprises an input coupling element 113, also called input surface of the waveguide 111. In the example shown, the input coupling element 113 is a diffraction grating having a Bragg structure allowing the radiation emitted by the laser source LS to be captured, and this radiation to be propagated along the waveguide 111 up to opposite the region 107 made of phase-change material. In the example shown, the input coupling element 113 comprises evenly-spaced portions of concentric rings, for example spaced by a distance equal to around 340 nm, and having each for example, when viewed from above, identical width, e.g. in the order of 340 nm. It advantageously allows the input coupling element 113 to be implemented by means of photolithography equipment having a resolution in the order of 300 nm, the width and spacing of the ring parts of the input coupling element 113 being even more low since the center wavelength of the laser radiation emitted from the source LS is small.

The ring portions of the input coupling element 113 are laterally separated from each other by parts of the insulating layer 103. As an example, the concentric-ring portions of the input coupling element 113 are made of a same material as the center region 111C of the waveguide 111. The center region 111C of the waveguide 111 and the rings of the input coupling element 113 are formed in a same insulating layer 115, for example. The insulating layer 115 extends for example over most of the top face of the holding support 101. In the example shown, parts of the insulating layer 115 are located on, and in contact with, the parts of the top faces of the conduction electrodes 105A and 105B.

For example, the input coupling element 113 is separated from the support substrate 101 by a distance equal to around 1,500 nm, within more or less 100 nm. It advantageously allows to take advantage of a constructive reflection of the optical wave transmitted by the waveguide 111 on the top face of the holding support 101, particularly in the case where the support substrate 101 is made of silicon, and to optimize a coupling between the laser source LS and the waveguide 111 by means of the input coupling element 113.

For example, the center region 111C of the waveguide 111 is separated from the support substrate 1001 by a distance higher than 1 μm. It advantageously allows the phenomena of optical absorption by the holding support 101 of the radiation transmitted by the waveguide 111 to be avoided or restricted. In the example shown, the center region 111C of the waveguide 111 is separated from the support substrate 101 by a same distance as the input coupling element 113. In this case, the center region 111C is separated from the support substrate 101 by a distance equal to around 1,500 nm, within more or less 100 nm. The conduction electrodes 105A and 105B, and the parts of the insulating layer 103 interposed between the support substrate 101 and the conduction electrodes 105A and 105B have for example a cumulative thickness equal to 1,500 nm, within more or less 100 nm. As an example, the conduction electrodes 105A and 105B have each a thickness equal to around 560 nm, and the parts of the insulating layer 103 interposed between the support substrate 101 and the conduction electrodes 105A and 105B have a thickness equal to around 940 nm.

As an alternative, an insulating layer, for example a layer made of silicon oxide having for example a thickness equal to around 20 nm, could be interposed between the support substrate 101 and the conduction electrodes 105A and 105B. In such case, the thickness of the conduction electrodes 105A and 105B and/or the thickness of the parts of the insulating layer 103 interposed between the support substrate 101 and the conduction electrodes 105A and 105B are suitable for achieving, between the bottom face of the region 107 made of phase-change material and the top face of the support substrate 101, a distance equal to around 1,500 nm, within more or less 100 nm. As an example, in the case where an insulating layer around 20 nm thick is provided between the insulating layer 115 and the conduction electrodes 105A and 105B, the conduction electrodes 105A and 105B have each a thickness equal to around 560 nm, and the parts of the insulating layer 103 interposed between the support substrate 101 and the conduction electrodes 105A and 105B have a thickness equal to around 920 nm.

In the example shown, the face of the region 107 made of phase-change material opposite the support substrate 101 (the top face of the region 107, in the orientation shown in FIGS. 1B and 1C) is coated by a passivating layer 117. In the present example, the passivating layer 117 is located on, and in contact with, the top face of the region 107 made of phase-change material. The passivating layer 117 allows the phase-change material of the region 107 to be protected against oxidizing. In the example shown, the side and top faces of the passivating layer 117 are coated by the insulating layer 103. In the example shown, a part of the insulating layer 103 extends on the top face of the passivating layer 117. For example, the passivating layer 117 has a thickness equal to around 20 nm. As an example, the passivating layer 117 is made of silicon nitride or germanium nitride. The passivating layer 117 was not shown in FIG. 1A, in order not to overload the drawing. As an alternative, the passivating layer 117 could be omitted.

Although it has not been shown in FIGS. 1A, 1B, and 1C, the switch 100 could further comprise contact elements and/or conductive tracks, e.g. metal tracks, located on, and in contact with, the top face of the insulating layer 103. The contact elements and/or conductive tracks are for example connected to the conduction electrodes 105A and 105B of the switch 100, and provide for example a function of routing the RF signals. The contact elements and/or conductive tracks are for example separated from the center region 111C of the waveguide 111 by a distance higher than 1 μm, for example higher than 1.5 μm. It allows the absorption, by the material of the contact elements and/or conductive tracks, of the radiation transmitted by the waveguide 111 to be avoided or restricted.

To trigger the switch 100 from the OFF state to the ON state, the region 107 is for example heated, using the laser source LS, via the waveguide 111, at a temperature T1 and for a duration d1. The temperature T1 and duration d1 are selected so as to cause a phase change of the material of the region 107 from the amorphous phase to the crystal phase. As an example, the temperature T1 is higher than a crystallizing temperature, and less than a melting temperature of the phase-change material, and the duration d1 ranges from 100 ns and 1 μs.

Oppositely, to trigger the switch 100 from the ON state to the OFF state, the region 107 is for example heated, using the laser source LS, via the waveguide 111, at a temperature T2 higher than the temperature T1, and for a duration d2, less than duration d1. The temperature T2 and duration d2 are selected so as to cause a phase change of the material of the region 107 from the crystal phase to the amorphous phase. As an example, the temperature T2 is higher than the melting temperature of the phase-change material and the duration d2 ranges from 10 ns and 100 ns.

One advantage of the switch 100 lays in the location of the waveguide 111 under the region 107 made of a phase-change material, i.e. between the support substrate 101 and the region 107 made of phase-change material. It allows the passivating layer 117 to be provided on the region 107 made of phase-change material in order to protect this material against oxidizing during the steps of manufacturing and using the switch 100. If the waveguide 111 was placed over the region 107 made of phase-change material, for example if the center region 111C of the waveguide was located on, and in contact with, the passivating layer 117, it would degrade the confinement of the optical wave within the waveguide, and it would reduce the coupling with the phase-change material of the region 107. Furthermore, providing the center region 111C of the waveguide 111 located over the region 107 made of a phase-change material would require to etch the material of the center region 111C in stopping on the phase-change material of the region 107, which would have the chance to degrade the latter. It would highly complicate the implementation of the switch 100.

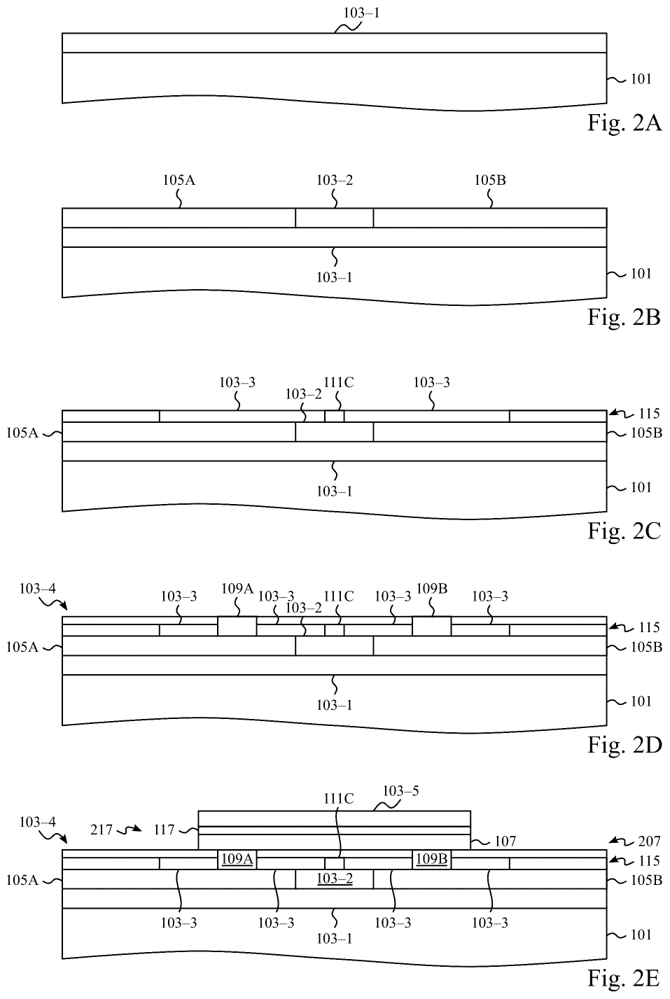

FIG. 2A, FIG. 2B, FIG. 2C, FIG. 2D, and FIG. 2E are schematic partial sectional views along the plane CC shown in FIG. 1A illustrating consecutive steps of an example method for manufacturing the switch 100 based on a phase-change material shown in FIGS. 1A, 1B, and 1C according to one embodiment.

More particularly, FIG. 2A illustrates a structure obtained at the end of a step of forming a part 103-1 of the insulating layer 103 on the side of the top face of the support substrate 101. For example, the part 103-1 of the insulating layer 103 is a thermal oxide layer located on, and in contact with, the top face of the support substrate 101.

More particularly, FIG. 2B illustrates a structure obtained at the end of steps of forming conduction electrodes 105A and 105B and another part 103-2 of the insulating layer 103 on the side of the top face of the support substrate 101.

As an example, one or more conductive layers, e.g. made of a metal or of a metal alloy, are first deposited consecutively on all top face of the part 103-1 of the insulating layer 103. During this step, the conductive layer(s) is (are) for example formed by PVD (Physical Vapor Deposition). The conduction electrodes 105A and 105B are then formed for example by photolithography then etching the conductive layer(s).

The part 103-2 of the insulating layer 103 is then deposited on the side of the top face of the support substrate 101. The part 103-2 of the insulating layer 103 thus coats parts of the top face of the part 103-1 not coated by the conduction electrodes 105A and 105B, and also the side and top faces of the conduction electrodes 105A and 105B. The part 103-2 of the insulating layer 103 is for example formed by PECVD (Plasma-Enhanced Chemical Vapor Deposition), for example by HDPCVD (High-Density Plasma Chemical Vapor Deposition). As an example, the part 103-2 of the insulating layer 103 has after depositing, a thickness of around 700 nm. For example, this thickness is then reduced by a Chemical and Mechanical Polishing (CMP) with stop on the conduction electrodes 105A and 105B, so that the part 103-2 of the insulating layer 103 flushes with the top face of the conduction electrodes 105A and 105B.

More particularly, FIG. 2C illustrates a structure obtained at the end of the steps of:
a) depositing the insulating layer 115 on the side of the top face of the support substrate 101;
b) structuring the insulating layer 115; and
c) depositing another part 103-3 of the insulating layer 103 on the side of the top face of the support substrate 101.

As an example, depositing the insulating layer 115 is performed by PECVD. The insulating layer 115 has for example a thickness equal to around 300 nm. The center region 111C and the input coupling element 113 (not shown in FIG. 2C) of the waveguide 111 are formed at the end of the step of structuring, for example by photolithography then etching, the insulating layer 115.

As an example, depositing the part 103-3 of the insulating layer 103 is performed by HPCVD. After depositing, the part 103-3 of the insulating layer 103 has for example a thickness equal to around 500 nm. The part 103-3 of the insulating layer 103 is then planarized, for example by an operation of chemical and mechanical polishing with stop on the parts of the insulating layer 115 remaining after structuring so that the part 103-3 of the insulating layer 103 flushes with the top face of the insulating layer 115.

When viewed from above, the insulating layer 115 has for example a surface equal to at least 35%, for example equal to at least 75%, and which could reach 90%, of the surface of the support substrate 101. It advantageously allows the stop of the step of chemical and mechanical polishing the part 103-3 of the insulating layer 103 to be facilitated.

More particularly, FIG. 2D illustrates a structure obtained at the end of the steps of depositing another part 103-4 of the insulating layer 103 on the side of the top face of the support substrate 101, and forming conductive vias 109A and 109B.

As an example, depositing the part 103-4 of the insulating layer 103 is performed by PECVD. For example, the part 103-4 of the insulating layer 103 has after depositing a thickness less than, or equal to, 100 nm, for example less than, or equal to, 50 nm, for example equal to around 20 nm.

As an alternative, depositing the part 103-4 of the insulating layer 103 could be omitted.

Conductive vias 109A and 109B are for example formed by photolithography then etching, for example Reactive Ion Etching (RIE), then depositing one or more conductive layers, for example made of a metal, or of a metal alloy, on the side of the top face of the support substrate 101.

In the example shown, the conductive vias 109A and 109B vertically extend from the top face of the part 103-4 of the insulating layer 103 up to the top faces of the conduction electrodes 105A and 105B, respectively. As an example, each conductive via 109A, 109B is made of a stack comprising a titanium nitride layer having for example a thickness equal to around 30 nm and formed by PVD coated by a tungsten layer formed by CVD (Chemical Vapor Deposition). The stack is then for example planarized by chemical and mechanical polishing with stop on the part 103-4 of the insulating layer 103, or with stop on the insulating layer 115, in the variant where the part 103-4 of the insulating layer 103 is omitted.

More particularly, FIG. 2E illustrates a structure obtained at the end of consecutive steps of:
a) depositing a layer 207 made of phase-change material on the side of the top face of the support substrate 101;
b) depositing an insulating layer 217 on the side of the top face of the support substrate 101;
c) depositing another part 103-5 of the insulating layer 103 on the side of the top face of the support substrate 101; and
d) structuring the layers 207 and 217 and the part 103-5 of the insulating layer 103.

As an example, the layer 207 made of phase-change material is deposited by PVD.

For example, the part 103-5 of the insulating layer 103 is structured by photolithography then etching, for example RIE etching, so as to keep only a region of the part 103-5 located in line with the future region 107 made of phase-change material. The part 103-5 of the insulating layer 103 is then for example used as hard mask to structure the passivating layer 217 and the layer made of a phase-change material 207. The layers 217 and 207 are for example structured concurrently, in the same step of photolithography then etching, for example RIE etching. The region 107 made of phase-change material and the passivating layer 117 described previously in reference to FIGS. 1A, 1B, and 1C are then obtained.

Starting from the structure shown in FIG. 2E, further steps of depositing another part of the insulating layer 103, having for example a thickness of around 2 μm, then polishing, for example by CMP, of this part of the insulating layer 103, for example so as to obtain a thickness of around 1.5 μm above the center region 111C of the waveguide 111, could be implemented. For example, the structure described above in reference to FIGS. 1A, 1B, and 1C is thus obtained. In order to simplify, FIGS. 1A, 1B, and 1C illustrate an example in which the parts 103-1, 103-2, 103-3, 103-4, and 103-5 of the insulating layer 103 are made of the same material. However, this example is not a limitation, the different parts of the insulating layer 103 described above in reference to FIGS. 2A-2E could alternatively be made of different materials.

Furthermore, although it was not shown in detail in the drawings, next steps of forming conductive vias vertically extending from the top face of the insulating layer 103 up to the top face of the conduction electrodes 105A and 105B, through the insulating layer 115, followed with steps of forming contact elements and/or conductive tracks located on, and in contact with, the top faces of these vias could then be implemented. As an example, the conductive vias are formed by performing opening by photolithography then etching, for example RIE etching, in the insulating layers 103 and 115, these opening being then for example filled with a metal or metal alloy.

As an example, each contact element is made of a stack comprising, from bottom to top in the orientation shown in FIGS. 1B and 1C:
a titanium layer having for example a thickness equal to around 10 nm;
a copper and alumina alloy having for example a thickness equal to around 1 μm;
a titanium layer having for example a thickness equal to around 10 nm; and
a nitride titanium layer having for example a thickness equal to around 100 nm.

The contact elements and/or conductive tracks are for example obtained by consecutively depositing, for example by PVD, layers made of the above-mentioned materials, these depositions being for example followed with a structuring step by photolithography then etching.

One advantage of the method described above in reference to the FIGS. 2A to 2E lays in the fact it allows the center region 111C of the waveguide 111 to be formed on a plane surface. In particular, during the step described in reference to FIG. 2B, a step of planarizing, for example by CMP, is performed prior to depositing the insulating layer 115. Particularly, the part 103-2 of the insulating layer 103 is for example planarized by CMP with stop on the layer in which the conduction electrodes 105A and 105B are formed, or the top face of the stack in which the conduction electrodes 105A and 105B are formed, for example a layer made of titanium nitride. The stop surface during this step is for example higher than 35%, for example around 50%, of the surface of the support substrate 101. It makes easier stopping the planarizing operation.

Those skilled in the art could have considered to form the center region 111C of the waveguide 111 over the region 107 made of phase-change material, would be complex to perform, since the phase-change material of the region 107 would have a chance to be damaged by chemical compounds used during the planarizing operation. A solution to overcome this issue could consist in providing on, and in contact with, the top face of the region 107 made of phase-change material, a etch-stop layer to be later removed, or to be taken into account in the operation of the switch 100. However, it would make complex implementing the switch 100. Furthermore, the surface of the region 107 made of phase-change material being for example less than 1% of the surface of the support substrate 101, stopping the planarizing operation would not be accurately controlled. Dummies elements, for example pads, made of phase-change material could be provided in order to increase the surface of the phase-change material, for example to obtain the regions made of phase-change material having a cumulative surface higher than 35% of the surface of the support substrate 101. However, this would make highly more complex the design and implementation of the switch 100.

Although it was not described in detail, the switch 100 could be integrated in any type of device comprising at least one switch optionally averaging adjustments within the capabilities of those skilled in the art based on reading the present description. Particularly, those skilled in the art will be able, based on the teaching of the present description, to integrate switches of the type of the switch 100 in RF applications, for example, within reconfigurable antennas with transmitter array or reflector network.

Various embodiments and variants have been described. Those skilled in the art will understand that certain features of these embodiments can be combined and other variants will readily occur to those skilled in the art. Finally, the practical implementation of the embodiments and variants described herein is within the capabilities of those skilled in the art based on the functional description provided hereinabove. In particular, the described embodiments are not limited to the specific examples of materials and sizes indicated in the present description.

1. An optically actuated phase-change-material-based switch formed on a support substrate, and comprising:
a region made of said phase-change material coupling first and second conduction electrodes of the switch; and
a waveguide interposed between the support substrate and the region made of said phase-change material, and including a center region made of a first material having a first optical index surrounded by a peripheral region made of a second material having a second optical index less than the first optical index.

2. The switch according to claim 1, wherein the center region of the waveguide is separated from the region made of said phase-change material with a distance less than, or equal to, 100 nm, preferably less than, or equal to, 50 nm, more preferably equal to around 20 nm.

3. The switch according to claim 1, wherein the waveguide further comprises an input coupling element having a Bragg structure comprising evenly spaced portions of concentric rings.

4. The switch according to claim 3, further comprising a laser source intended to irradiate the coupling element with a laser radiation having a center wavelength equal to around 915 nm.

5. The switch according to claim 3, wherein the input coupling element is separated from the support substrate with a distance equal to around 1,500 nm within more or less 100 nm.

6. The switch according to claim 1, wherein the center region of the waveguide is separated from the support substrate with a distance equal to around 1,500 nm within more or less 100 nm.

7. The switch according to claim 1, further comprising first and second conductive vias extending between the region made of said phase-change material and the first and second conduction electrodes, respectively.

8. The switch according to claim 7, wherein the center region of the waveguide is separated from the first and second conductive vias with a distance higher than, or equal to, 0.3 μm.

9. The switch according to claim 1, wherein the region made of said phase-change material is coated with a passivating layer.

10. The switch according to claim 1, wherein the center and peripheral regions of the waveguide are made of silicon nitride and silicon oxide respectively.

11. The switch according to claim 1, wherein the center region of the waveguide is around 300 nm high and around 600 nm wide.

12. A method for manufacturing an optically actuated phase-change-material-based switch comprising the consecutive following steps:
a) forming, on a support substrate, first and second conduction electrodes of the switch;
b) forming, on the support substrate, a waveguide including a center region made of a first material having a first optical index surrounded by a peripheral region made of a second material having a second optical index less than a first optical index; and
c) forming, on the support substrate, a region made of said phase-change material coupling the first and second conduction electrodes of the switch, the waveguide being interposed between the support substrate and the region made of said phase-change material.
